(19) United States
(12) Patent Application Publication
(10) Pub. No.: US 2026/0047089 A1
(43) Pub. Date: Feb. 12, 2026

(54) FLASH MEMORY AND MANUFACTURING METHOD THEREOF

(71) Applicant: Winbond Electronics Corp., Taichung City (TW)

(72) Inventors: Chih-Jung NI, Taichung City (TW); Cheng-Pu HO, Changhua County (TW); Ying-Ju CHEN, Taichung City (TW); Min-Liang CHENG, Taichung City (TW)

(21) Appl. No.: 19/293,273

(22) Filed: Aug. 7, 2025

(30) Foreign Application Priority Data
Aug. 8, 2024 (TW) 113129740

(51) Int. Cl. H10B 41/30

(52) U.S. Cl. CPC H10B 41/30

(57) ABSTRACT

A method of manufacturing a flash memory is provided. The method includes: forming a pad oxide on a substrate in an array region and a peripheral region; and performing an array region pad oxide etching batch control process. Performing the array region pad oxide etching batch control process includes: measuring the thickness of the pad oxide in the array region; and etching the pad oxide in the array region until the thickness reaches the desired value. The method further includes: forming a tunnel oxide layer on the substrate. The tunnel oxide layer comprises the pad oxide, and the edge thickness of the tunnel oxide layer is greater than the central thickness of the tunnel oxide layer.

### CROSS REFERENCE TO RELATED APPLICATIONS

This application claims priority of Taiwan Patent Application No. 113129740, filed on Aug. 8, 2024, the entirety of which is incorporated by reference herein.

### BACKGROUND OF THE INVENTION

### Field of the Invention

The present disclosure relates to a semiconductor device and a manufacturing method thereof, and in particular to a method of manufacturing flash memory that uses batch control to adjust the thickness.

### Description of the Related Art

In the traditional flash memory process, self-aligned floating gates are formed by filling floating gate materials between isolation structures. As the manufacturing process of flash memory continues to scale down, the aspect ratio of the floating gate increases, while variations in the top spacing between isolation structures on incoming wafers are observed. If the top profile of the isolation structure or the spacing between isolation structures on the wafer does not align with the intended process conditions for the floating gate during fabrication, pitting may occur in the floating gate. This, in turn, leads to yield loss and reliability degradation. To address this issue, conventional flash memory manufacturing processes first measure the top spacing between isolation structures on incoming wafers and then sort the wafers into different groups based on these measurements. For each group, different process conditions, such as the deposition and etching amounts for forming the floating gate, are applied. Wafers within the same group are then batched together and processed in the furnace using the corresponding recipe. However, this strict grouping and batching approach significantly reduces productivity and limits the ability to achieve high-volume manufacturing.

### BRIEF SUMMARY OF THE INVENTION

Embodiments of the present invention provide a flash memory and a method for manufacturing a flash memory that address corner thickness thinning of the tunnel oxide layer and floating gate pitting. The described approach aims to enhance yield and reliability without fabricating floating gate in batches using different process conditions.

An embodiment of the present invention provides a method for manufacturing a flash memory. The method includes: forming a pad oxide on a substrate in an array region and a peripheral region; and performing an array region pad oxide etching batch control process. Performing array region pad oxide etching batch control process includes: measuring the thickness of the pad oxide in the array region; and etching the pad oxide in the array region until the thickness reaches the desired value. The method further includes forming a tunnel oxide layer on the substrate. The tunnel oxide layer comprises the pad oxide, and the edge thickness of the tunnel oxide layer is greater than the central thickness of the tunnel oxide layer.

An embodiment of the present invention provides a flash memory, including a substrate, a plurality of isolation structures disposed in the substrate, a tunnel oxide layer disposed on the substrate, a floating gate disposed on the tunnel oxide layer, a dielectric liner disposed along the sidewalls and the top surface of the floating gate, and a control gate disposed on the dielectric liner. The edge thickness of the tunnel oxide layer is greater than the central thickness of the tunnel oxide layer. The tunnel oxide layer includes a pad oxide, and the thickness of the pad oxide is controlled by an array region pad oxide etching batch control process.

According to embodiments of the present invention, the shape of the subsequently formed floating gate and the thickness and the profile of the tunnel oxide layer may be precisely controlled to improve productivity and reliability.

### BRIEF DESCRIPTION OF THE DRAWINGS

FIGS. 1A and 1B are flowcharts illustrating a method of manufacturing a flash memory according to some embodiments of the present invention.

FIGS. 2-14 are cross-sectional views of a method of manufacturing a flash memory in different stages according to some embodiments of the present invention.

FIG. 15 is a cross-sectional view of a flash memory according to some embodiments of the present invention.

### DETAILED DESCRIPTION OF THE INVENTION

The following provides different embodiments for implementing the flash memory of the present disclosure. However, these are only examples and are not intended to limit the disclosure. For example, when the description states that a first component is formed on a second component, unless otherwise specified, this may refer to embodiments where the two components are either in direct contact or separated. For simplicity and clarity, the same or similar element symbols may be used across different embodiments to denote the same or similar elements, but is not intended to limit the relationships among those embodiments. Additional steps may be included before, during, or after the manufacturing methods mentioned in this disclosure, and some steps may be replaced or deleted in alternative embodiments.

Embodiments of the present invention accurately control the shape of the subsequently formed floating gate and the thickness and profile of the tunnel oxide layer through multiple batch controls, thereby improving the yield and reliability of the flash memory.

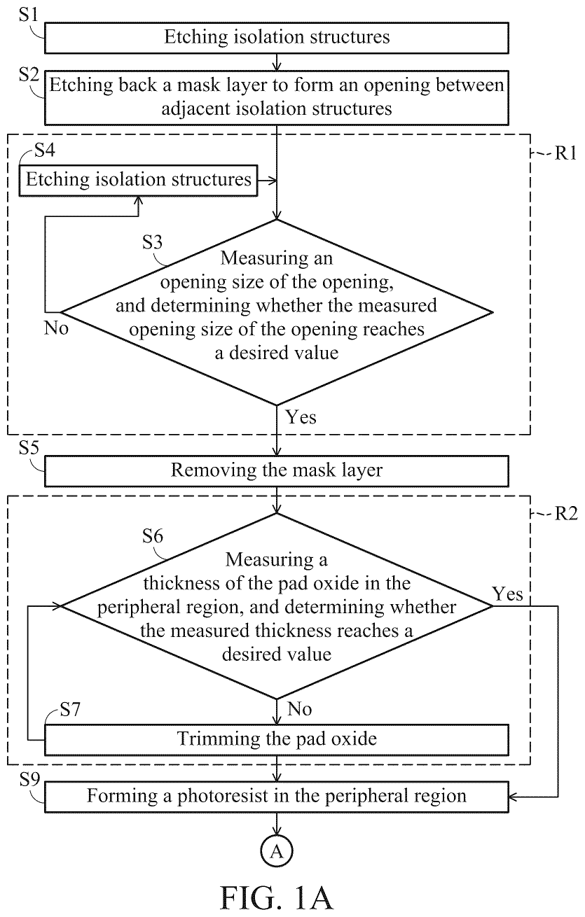

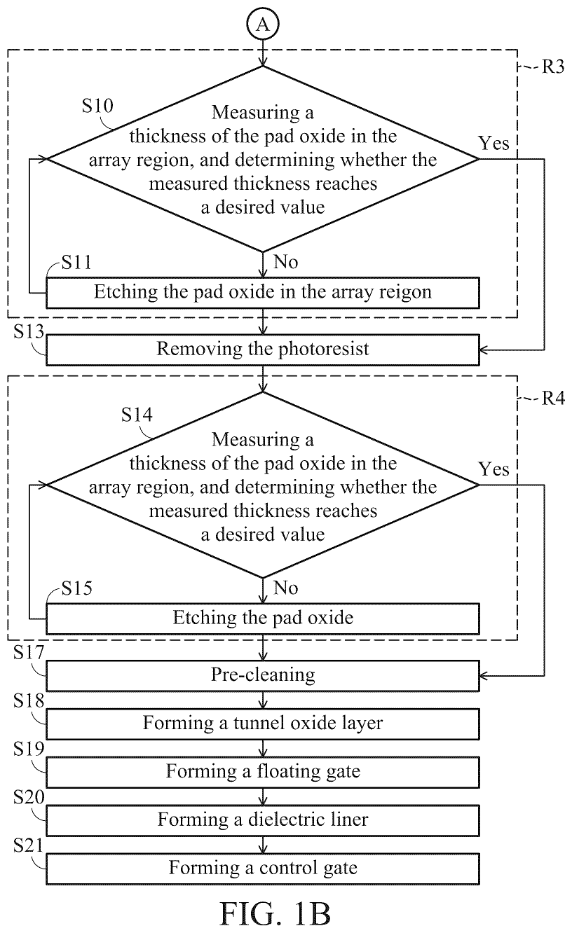

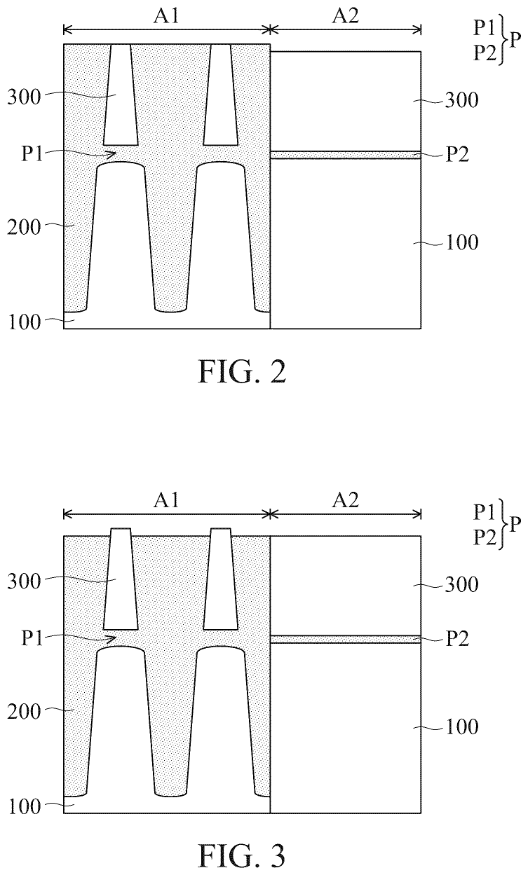

FIGS. 1A and 1B are flowcharts illustrating a method of manufacturing a flash memory according to some embodiments of the present invention. FIGS. 2-14 are cross-sectional views of a method of manufacturing a flash memory in different stages according to some embodiments of the present invention. FIG. 15 is a cross-sectional view of a flash memory according to some embodiments of the present invention. In some embodiments, the flash memory may be an NOR flash memory.

As shown in FIG. 2, a pad oxide P and a mask layer 300 are formed on the substrate 100 having an array region A1 and a peripheral region A2. Furthermore, an isolation structure 200 is formed in the substrate 100. The peripheral region A2 surrounds the outside of the array region A1, for example. In some embodiments, the thickness of the pad oxide P1 formed in the array region A1 is greater than the thickness of the pad oxide P2 formed in the peripheral region A2. In an embodiment, the peripheral region A2 may include a flat area for optical instruments to measure thickness. It should be noted that the array region A1 and the peripheral region A2 shown in the figures are only examples of a portion of each area, rather than a connected area between the two.

In some embodiments, the substrate 100 may include silicon, gallium arsenide, gallium nitride, germanium silicide, silicon on insulator (SOI), other suitable semiconductor materials, or combinations thereof. In some embodiments, other structures, such as doped regions (not shown), may also be formed in the substrate 100. In this embodiment of the present invention, the substrate 100 is a silicon substrate.

In some embodiments, the mask layer 300 may be formed on the pad oxide P through a deposition process. In some embodiments, the mask layer 300 may include nitride, oxynitride, carbide, or other suitable dielectric materials. The isolation structures 200 may be selected from materials similar to but different from the mask layer 300 to facilitate subsequent selective removal of the mask layer 300. For example, the isolation structures 200 may be silicon oxide, and the mask layer 300 may be silicon nitride. The isolation structures 200 may be formed using any known process. The material of the pad oxide P may be an oxide, such as silicon oxide. In this embodiment, since the material of the pad oxide P and the isolation structure 200 are the same, the boundary between the two is not shown. In other embodiments, the material of the pad oxide P and the material of the isolation structure 200 may also be different.

Next, referring to FIGS. 1A and 3, the isolation structures 200 may be selectively etched back (step S1), and residue (such as oxides) on the mask layer 300 may be removed to improve efficiency of subsequent processing of etching back the mask layer 300. In some embodiments, step S1 may include wet etching and vapor etching processes.

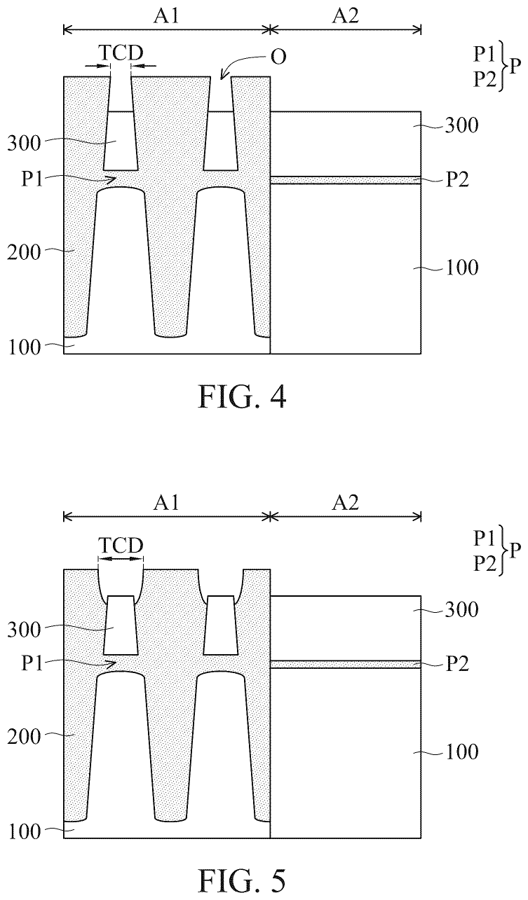

Next, referring to FIGS. 1A and 4, the mask layer 300 is etched back, so that the top surface of the etched-back mask layer 300 is lower than the top surface of the isolation structure 200, thereby forming an opening O between adjacent isolation structures 200 (step S2). In some embodiments, the etching back of the mask layer 300 may include a wet etching process, such as using an acidic solution.

Next, continue to refer to FIG. 1A, FIG. 4 and FIG. 5, an isolation structure etching batch control process R1 is performed on the isolation structure 200 in the array region A1. In this embodiment, the isolation structure etching batch control process R1 includes step S3 and step S4. In step S3, the opening size TCD between adjacent isolation structures 200 is measured for each wafer, that is, the spacing size between the top surfaces of adjacent isolation structures 200 is measured. Furthermore, whether the measured opening size TCD reaches the desired value is determined.

When the measured opening size TCD does not reach the desired value, step S4 is performed. In step S4, the etching time for the isolation structure 200 of each wafer is determined according to the measured opening size TCD, and the isolation structure 200 is etched according to the determined etching time, as shown in FIG. 5. In this embodiment, as the measured opening size TCD becomes narrower, the determined etching time becomes longer to ensure that different wafers have consistent opening size TCD. A database may be established in advance based on the relationship between etching amount and etching time to determine the etching time for different opening size TCD. In some embodiments, the isolation structures 200 may be etched through a wet etching process.

In this embodiment, the isolation structures 200 are etched by an isotropic wet etching process, so the upper portion of the isolation structure 200 may have an arc-shaped lead angle. In addition, by improving the etching selectivity for the isolation structure 200, the impact on the mask layer 300 in the isolation structure etching batch control process R1 may be reduced.

After step S4 is completed, return to step S3 to measure the opening size TCD between adjacent isolation structures 200 for each wafer again, and determine whether the measured opening size TCD reaches the desired value. By using the isolation structure etching batch control process R1 described in this embodiment, different wafers can be processed to achieve a more uniform opening size TCD. This allows for better compatibility with subsequent floating gate filling processes and reduces the occurrence of floating gate pitting, which can enhance yield and reliability.

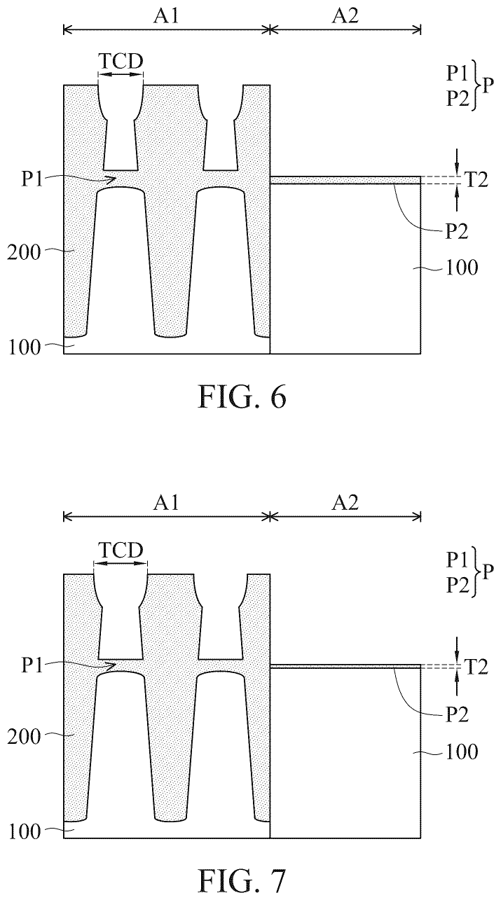

Continuing to refer to FIG. 1A and FIG. 6, when the measured opening size TCD reaches the desired value, the mask layer 300 is removed through an etching process to expose the pad oxide P (step S5).

Next, continue to refer to FIG. 1A and FIGS. 6-7, a peripheral region pad oxide etching batch control process R2 is performed on the flash memory. In this embodiment, the peripheral region pad oxide etching batch control process R2 includes steps S6 and S7. In step S6, the thickness T2 of the pad oxide P2 in the peripheral region A2 is measured, and it is determined whether the thickness T2 reaches the desired value. In some embodiments, the thickness T2 may be measured by a thin film analyzer.

If the thickness T2 does not reach the desired value, in step S7, the pad oxide P is etched (trimmed) according to the thickness T2, as shown in FIG. 7. Specifically, a thinner thickness T2 results in a shorter etching time, while a thicker thickness T2 requires a longer etching time, allowing for consistent thickness T2 across flash memories from different wafers. A database may be established in advance to correlate etching amount with etching time, enabling determination of the appropriate etching time for different thicknesses T2. In this embodiment, in step S7, the pad oxides P1 and P2 are etched. After step S7 is completed, return to step S6 to measure the thickness T2 of the pad oxide P2 in the peripheral region A2 for each wafer again, and determine whether the thickness T2 reaches the expected value.

It should be noted that if the pad oxide P is damaged before the tunnel oxide layer is formed, the quality of the subsequently formed tunnel oxide layer may be affected, thereby reducing the yield. Especially for the thinner pad oxide P2 in the peripheral region A2, if the corners of the pad oxide P2 are damaged, it may cause the corners of the subsequent tunnel oxide layer recessed, thereby reducing the yield. Therefore, this embodiment uses the peripheral region pad oxide etching batch control process R2 to accurately control the thickness of the pad oxide P2, so that the thickness T2 is substantially consistent, and the pad oxide P is prevented from being damaged before the tunnel oxide layer is formed, thereby improving the quality of the tunnel oxide layer (such as thickness uniformity) and improving yield.

In some embodiments, through the peripheral region pad oxide etching batch control process R2, the opening size TCD between the isolation structures 200 may be further widened, thereby avoiding the subsequent formation of floating gates from pitting and thus improving yield and reliability.

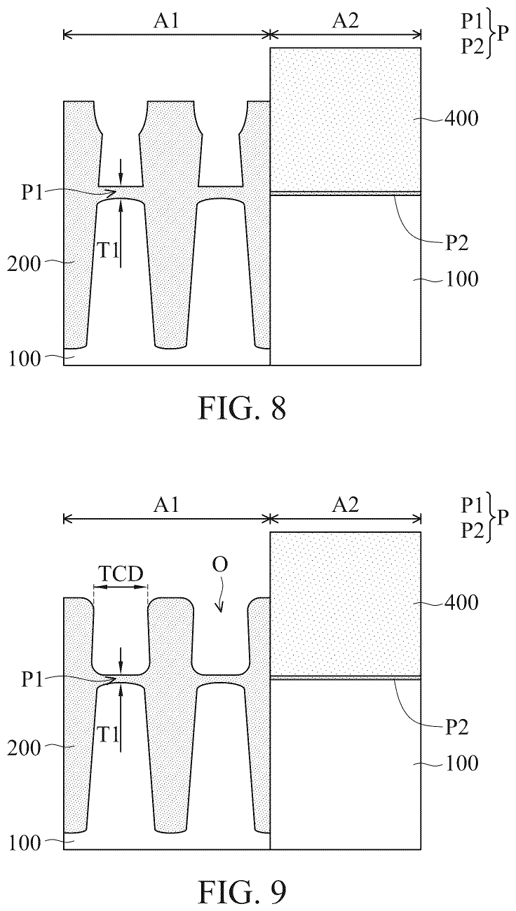

Continuing to refer to FIGS. 1A and 8, when the thickness T2 reaches the desired value, step S9 is performed to form a photoresist 400 that shields the peripheral region A2 and exposes the array region A1. In some embodiments, the elements in the array region A1 may be subjected to ion implantation processes, thermal processes, and the like according to actual needs, but the invention is not limited thereto.

Next, continuing to refer to FIG. 1B and FIGS. 8-9, an array region pad oxide etching batch control process R3 in the array region A1 of the flash memory is performed. In this embodiment, the array region pad oxide etching batch control process R3 includes steps S10 and S11. In step S10, the thickness T1 of the pad oxide P1 in the array region A1 is measured, and it is determined whether the thickness T1 reaches the desired value.

If the thickness T1 does not reach the desired value, in step S11, the pad oxide P1 is etched (trimmed) according to the thickness T1, as shown in FIG. 9. Specifically, a thinner thickness T1 results in a shorter etching time, while a thicker thickness T1 requires a longer etching time, allowing for consistent thickness T1 across flash memories from different wafers. A database may be established in advance to correlate etching amount with etching time, enabling determination of the appropriate etching time for different thicknesses T1. After step S11, repeat step S10 to remeasure the thickness T1 of the pad oxide P1 in the array region A1 for each wafer, and determine whether the thickness T1 reaches the desired value. In some embodiments, the array region pad oxide etching batch control process R3 rounds the corners of the top surface of the pad oxide P1 (that is, the bottom surface of the opening O has rounded corners), widening the opening size TCD between the isolation structures 200.

It should be noted that the uneven thickness of the pad oxide P1 may affect the quality of the subsequently formation of tunnel oxide layer, thereby affecting the breakdown voltage of the flash memory. Therefore, through the array region pad oxide etching batch control process R3 provided in this embodiment, the thickness T1 of the pad oxide P1 of different wafers may be gradually and accurately controlled, thereby improving the thickness uniformity of the pad oxide P1. In this way, the quality of the tunnel oxide layer (such as thickness uniformity) may be improved, thereby controlling the breakdown voltage of the flash memory within an appropriate range. In addition, through the array region pad oxide etching batch control process R3 provided in this embodiment, the bottom surface of the opening O may have rounded corners and the opening size TCD is further widened, thereby avoiding the subsequent formation of floating gates from pitting and thus improving yield and reliability.

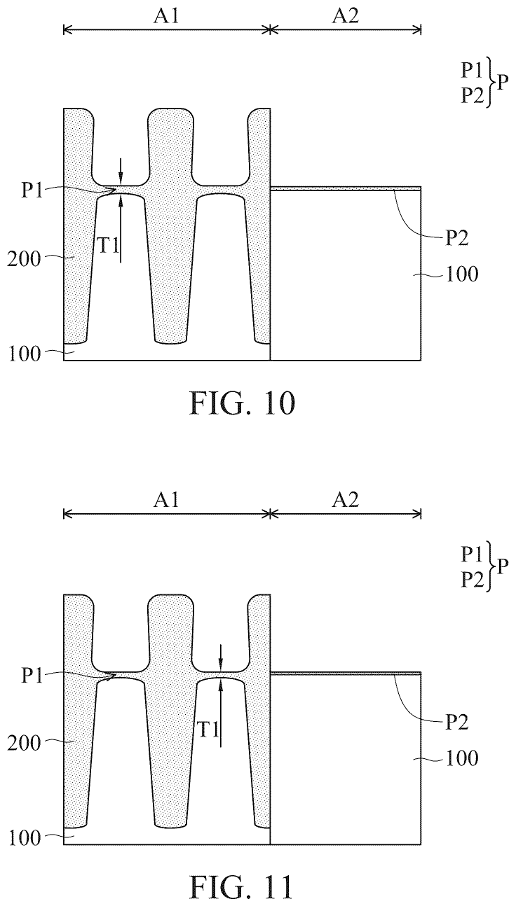

Continuing to refer to FIG. 1B and FIG. 10, when the thickness T1 reaches the desired value, step S13 is performed to remove the photoresist 400. The removal method may include conventional methods such as photoresist ashing and cleaning, which will not be described here. In some embodiments, a thermal oxidation process, a thermal diffusion process, and the like may be performed according to actual needs, but the invention is not limited thereto.

Next, continuing to refer to FIG. 1B and FIGS. 10-11, a pad oxide etching batch control process R4 on the flash memory is performed. In this embodiment, the pad oxide etching batch control process R4 includes steps S14 and S15. In step S14, the thickness T1 of the pad oxide P1 in the array region A1 is measured, and it is determined whether the thickness T1 reaches the desired value.

If the thickness T1 does not reach the desired value, in step S15, the pad oxide P is etched (trimmed) according to the thickness T1, as shown in FIG. 11. Specifically, a thinner thickness T1 results in a shorter etching time, while a thicker thickness T1 requires a longer etching time, allowing for consistent thickness T1 across flash memories from different wafers. A database may be established in advance to correlate etching amount with etching time, enabling determination of the appropriate etching time for different thicknesses T1. In this embodiment, in step S15, the pad oxides P1 and P2 are etched. After step S15, repeat step S14 to remeasure the thickness T1 of the pad oxide P1 in the array region A1 for each wafer, and determine whether the thickness T1 reaches the desired value. Through the pad oxide etching batch control process R4, the quality (such as thickness uniformity) of the tunnel oxide layer may be improved, thereby controlling the breakdown voltage of the flash memory within an appropriate range.

It should be noted that since the thickness of the pad oxide P1 obtained by the array region pad oxide etching batch control process R3 may still be slightly different, the pad oxide etching batch control process R4 is used to make the thickness T1 more accurately achieve the desired value. In some embodiments, the concentration of the etching liquid used in step S15 is lower than the concentration of the etching liquid used in step S11.

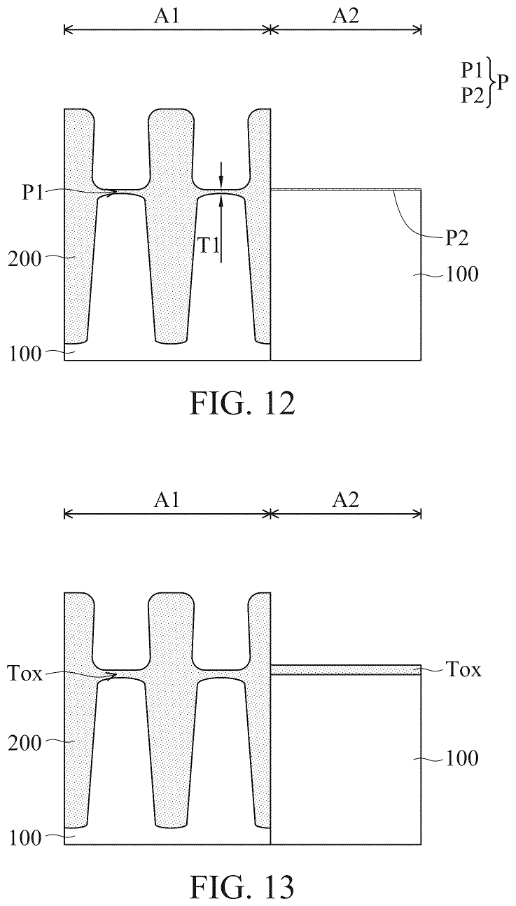

Continuing to refer to FIGS. 1B and 12, when the thickness T1 reaches the desired value, step S17 is performed to pre-clean the flash memory to completely remove the pad oxide P2 in the peripheral region A2. When the pad oxide P2 in the peripheral region A2 is completely removed, due to the influence of the aforementioned oxidation process, a small amount of the pad oxide P1 may still remain in the array region A1, and the thickness of the pad oxide P1 at the edge is greater than that at the center.

Continuing to refer to FIG. 1B and FIG. 13, step S18 is performed to form a tunnel oxide layer Tox. In one embodiment, an oxide layer may be formed on the pad oxide P to form a tunnel oxide layer Tox including the pad oxide P. In this embodiment, the thickness of the tunnel oxide layer Tox on both sides is greater than that at the center.

In some embodiments, the tunnel oxide layer Tox may include a material similar to or identical to the pad oxide P, which will not be described again here. In the embodiment of the present invention, since the tunnel oxide layer Tox and the pad oxide P are made of the same material, such as silicon oxide, there is no obvious boundary in the drawings. In some embodiments, the tunnel oxide layer Tox may be formed through an oxidation process or a deposition process similar to the above, which will not be described again.

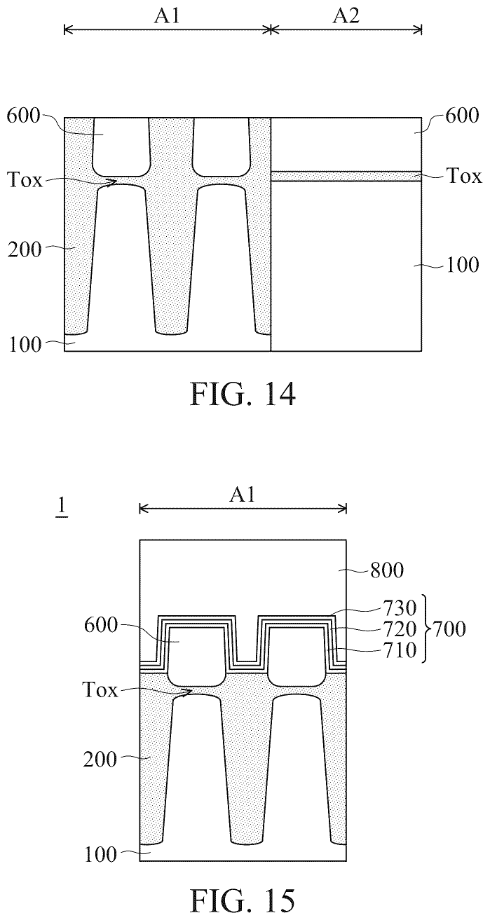

Continuing to refer to FIG. 1B and FIG. 14, step S19 is performed to form a floating gate 600 on the tunnel oxide layer Tox. In this embodiment, the bottom surface of the opening O formed according to the array region pad oxide etching batch control process R3 has rounded corners, and the floating gate 600 filled in the opening O also has rounded corners at the corners of the bottom surface. In the array region A1 and the peripheral region A2, the floating gate 600 may have a substantially flat top surface. In some embodiments, the material of floating gate 600 may include doped polysilicon (such as p-type doped polysilicon or n-type doped polysilicon).

Only the structure of the array region A1 will be described in detail below for simplicity.

Referring to FIG. 1B and FIG. 15, steps S20 and S21 are performed to form a dielectric liner 700 on the floating gate 600, and form a control gate 800 on the dielectric liner 700. In some embodiments, the isolation structure 200 is first etched back to make the floating gate 600 protrude from the top surface of the isolation structure 200, thereby increasing the subsequent gate coupling ratio. Next, the dielectric liner 700 is formed on the top surface of the isolation structure 200 and on the sidewalls and top surface of the floating gate 600. The dielectric liner 700 may be a polycrystalline silicon interlayer dielectric (interpoly dielectrics) and includes an oxide 710, a nitride 720, and an oxide 730 in sequence. In some embodiments, the control gate 800 may include materials similar to the floating gate 600, which will not be described again here. It should be noted that after the control gate 800 is formed, other conventional processes may be performed according to actual needs to complete the flash memory. Other known manufacturing processes will not be described again here.

In summary, embodiments of the present invention reduce the phenomenon of floating gate pitting by making the profile of the flash memory consistent with the set floating gate process conditions. In addition, the embodiment of the present invention eliminates the traditional strict grouping and batching approach, thereby improving productivity. Moreover, embodiments of the present invention form the pad oxide with uniform thickness by employing the peripheral region pad oxide etching batch control process, the array region pad oxide etching batch control process or the pad oxide etching batch control process, thereby improving yield and reliability. In addition, through the isolation structure etching batch control process and/or the peripheral region pad oxide etching batch control process, the top spacing of the isolation structures in the array region may be adjusted to control the floating gate to have a substantially identical shape (i.e., different incoming wafers have approximately the same spacing dimensions), thereby improving yield and reliability.

The present invention is suitable for producing scaling down flash memory to increase the total number of dies on the wafer. Therefore, the present invention may reduce the production cost and energy consumption of manufacturing a single IC, and reduce the production energy consumption of subsequent packaging, thereby reducing carbon emissions in the flash memory production process. In addition, since the reliability and yield of the flash memory of the present invention are improved, the present invention provides a green semiconductor technology.

Several embodiments are summarized above so that those with ordinary knowledge in the relevant technical field can better understand the viewpoints of the embodiments of the present disclosure. Those with ordinary skill in the art should understand that they may design or modify other processes and structures based on the embodiments of the present disclosure to achieve the same purposes and/or advantages as the embodiments introduced here. Those with ordinary knowledge in the relevant technical field should also understand that such equivalent processes and structures do not deviate from the spirit and scope of the disclosure, and they may make various changes, substitutions and substitutions without departing from the spirit and scope of this disclosure.

What is claimed is:

1. A method of manufacturing a flash memory, comprising:
forming a pad oxide on a substrate in an array region and a peripheral region;
performing an array region pad oxide etching batch control process, which comprises:
measuring a thickness of the pad oxide in the array region; and
etching the pad oxide in the array region until the thickness reaches a desired value; and
forming a tunnel oxide layer on the substrate, wherein the tunnel oxide layer comprises the pad oxide, and an edge thickness of the tunnel oxide layer is greater than a central thickness of the tunnel oxide layer.

2. The method of manufacturing a flash memory as claimed in claim 1, wherein before performing the array region pad oxide etching batch control process, the method further comprises:
forming a mask layer on the pad oxide;
forming a plurality of isolation structures in the substrate;
etching back the plurality of isolation structures; and
etching back the mask layer so that a top surface of the etched-back mask layer is lower than a top surface of each isolation structure, thereby forming an opening between adjacent isolation structures,
wherein the thickness of the pad oxide in the array region is greater than a thickness of the pad oxide in the peripheral region.

3. The method of manufacturing a flash memory as claimed in claim 2, further comprising:
performing an isolation structure etching batch control process, wherein performing the isolation structure etching batch control process comprises:
measuring an opening size of the opening; and
etching the plurality of isolation structures in the array region until the opening size reaches a desired value.

4. The method of manufacturing a flash memory as claimed in claim 2, further comprising:
removing the mask layer; and
performing a peripheral region pad oxide etching batch control process, wherein the peripheral region pad oxide etching batch control process comprises:
measuring the thickness of the pad oxide in the peripheral region; and
etching the pad oxide until the thickness reaches a desired value.

5. The method of manufacturing a flash memory as claimed in claim 3, wherein after performing the isolation structure etching batch control process, the method further comprises:
removing the mask layer; and
after removing the mask layer, performing a peripheral region pad oxide etching batch control process, wherein performing the peripheral region pad oxide etching batch control process comprises:
measuring the thickness of the pad oxide in the peripheral region; and
etching the pad oxide until the thickness reaches a desired value.

6. The method of manufacturing a flash memory as claimed in claim 1, further comprising:
forming a photoresist on the pad oxide in the peripheral region before performing the array region pad oxide etching batch control process; and
removing the photoresist after performing the array region pad oxide etching batch control process.

7. The method of manufacturing a flash memory as claimed in claim 6, wherein after removing the photoresist, the method further comprises performing a pad oxide etching batch control process, wherein performing the pad oxide etching batch control process comprises:
measuring the thickness of the pad oxide in the array region; and
etching the pad oxide until the thickness reaches a desired value.

8. The method of manufacturing a flash memory as claimed in claim 6, wherein after performing the pad oxide etching batch control process, the method further comprises:
performing a pre-cleaning to completely remove the pad oxide in the peripheral region and to partially remove the pad oxide in the array region.

9. The method of manufacturing a flash memory as claimed in claim 1, wherein after performing the pad oxide etching batch control process, the method further comprises:
forming a floating gate on the tunnel oxide layer;
forming a dielectric liner on the floating gate; and
forming a control gate on the dielectric liner.

10. The method of manufacturing a flash memory as claimed in claim 5, further comprising:
forming a photoresist on the pad oxide in the peripheral region before performing the array region pad oxide etching batch control process;
removing the photoresist after performing the array region pad oxide etching batch control process; and
performing a pad oxide etching batch control process after removing the photoresist, wherein performing the pad oxide etching batch control process comprises:
measuring the thickness of the pad oxide in the array region; and
etching the pad oxide until the thickness reaches a desired value.

11. The method of manufacturing a flash memory as claimed in claim 7, wherein a concentration of the etching liquid used in etching the pad oxide in the pad oxide etching batch control process is lower than a concentration of the etching liquid used in etching the pad oxide in the array region pad oxide etching batch control process.

12. The method of manufacturing a flash memory as claimed in claim 1, wherein performing the array region pad oxide etching batch control process comprises:
establishing a database in advance to correlate an etching amount with an etching time;
measuring the thickness of the pad oxide in the array region; and
according to the measured thickness and a desired value, using the database to get the etching amount and the etching time;
etching the pad oxide in the array region by the etching amount and the etching time.

13. A flash memory, comprising:
a substrate;
a plurality of isolation structures disposed in the substrate;
a tunnel oxide layer disposed on the substrate, wherein an edge thickness of the tunnel oxide layer is greater than a central thickness of the tunnel oxide layer, wherein the tunnel oxide layer comprises a pad oxide, and a thickness of the pad oxide is controlled by an array region pad oxide etching batch control process and;
a floating gate disposed on the tunnel oxide layer;
a dielectric liner disposed along sidewalls and a top surface of the floating gate; and
a control gate disposed on the dielectric liner.

14. The flash memory as claimed in claim 13, wherein the floating gate has a rounded corner at a bottom surface.

15. The flash memory as claimed in claim 13, wherein the dielectric liner is polycrystalline silicon interlayer dielectric.

16. The flash memory as claimed in claim 13, wherein the dielectric liner comprises an oxide, a nitride, and an oxide in sequence from the substrate.

17. The flash memory as claimed in claim 13, wherein the floating gate protrudes from a top surface of the plurality of isolation structures.

18. The flash memory as claimed in claim 13, wherein the top spacing between the isolation structures are controlled by an isolation structure etching batch control process.
